(19) United States
(12) Patent Application Publication
(10) Pub. No.: US 2022/0308979 A1
(43) Pub. Date: Sep. 29, 2022

(54) INFORMATION PROCESSING DEVICE, INFORMATION PROCESSING METHOD, AND NON-TRANSITORY STORAGE MEDIUM

(71) Applicant: TOYOTA TECHNICAL DEVELOPMENT CORPORATION, Toyota (JP)

(72) Inventors: Yuji NAKATSUKA, Toyota-shi (JP); Ayaka SUGIMOTO, Toyota-shi (JP); Noriyasu SUZUKI, Toyota-shi (JP); Akira KAWAGUCHI, Toyota-shi (JP)

(73) Assignee: TOYOTA TECHNICAL DEVELOPMENT CORPORATION, Toyota (JP)

(21) Appl. No.: 17/669,958

(22) Filed: Feb. 11, 2022

(30) Foreign Application Priority Data
Mar. 29, 2021 (JP) 2021-055145

(51) Int. Cl. G06F 11/34; G06F 9/50

(52) U.S. Cl. CPC G06F 11/3457; G06F 9/5077; G06F 11/3409

(57) ABSTRACT

An information processing device includes a processor. The processor is configured to acquire a calculation model, and divide the acquired calculation model at elements constituting the calculation model to generate a plurality of components. The processor is configured to estimate a first index and a second index. The first index is related to a calculation resource at a time when the calculation model is divided into the components. The second index is related to a calculation resource at a time when the calculation model is not divided into the components. The processor is configured to make determination as to whether a third index is smaller than a preset threshold. The third index is calculated based on the first index and the second index. The processor is configured to perform control to output a result of the determination.

### CROSS-REFERENCE TO RELATED APPLICATION

This application claims priority to Japanese Patent Application No. 2021-055145 filed on Mar. 29, 2021, incorporated herein by reference in its entirety.

### BACKGROUND

### 1. Technical Field

The present disclosure relates to an information processing device, an information processing method, and a non-transitory storage medium.

### 2. Description of Related Art

A simulation is performed for calculation on a target model. When the scale of the target model increases, a long period is required for a calculation process. In a technology described in Japanese Unexamined Patent Application Publication No. 2010-033567 (JP 2010-033567 A), a target model is divided into a plurality of submodels and a calculation process is performed in parallel to achieve a high-speed calculation process.

### SUMMARY

When the model is divided as described above, the calculation efficiency changes depending on how the model is divided. Therefore, it is necessary to divide the model so that the calculation efficiency relatively increases.

The present disclosure provides an information processing device, an information processing method, and a non-transitory storage medium in which an efficient calculation process can be performed.

An information processing device of a first aspect of the present disclosure includes a processor. The processor is configured to acquire a calculation model. The processor is configured to divide the acquired calculation model at elements constituting the calculation model to generate a plurality of components. The processor is configured to estimate a first index and a second index. The first index is related to a calculation resource at a time when the calculation model is divided into the components. The second index is related to a calculation resource at a time when the calculation model is not divided into the components. The processor is configured to make determination whether a third index is smaller than a preset threshold. The third index is calculated based on the first index and the second index. The processor is configured to perform control to output a result of the determination.

In the information processing device according to the first aspect of the present disclosure, the processor may be configured to identify a component that the processor makes the determination that the third index is smaller than the threshold. The third index may be calculated by division with the first index as a numerator and the second index as a denominator. The processor may be configured to output information on the identified component.

In the information processing device according to the first aspect of the present disclosure, the processor may be configured to, when the processor determines that the third index is equal to or larger than the threshold, further divide a first component at an element constituting the first component to further generate a plurality of components. The first component may be a component on which the determination is made that the third index is equal to or larger than the threshold.

In the information processing device according to the first aspect of the present disclosure, the processor may be configured to divide the calculation model such that the components to perform integral communication for using a calculation result of a component in a preceding stage in a component in a succeeding stage.

In the information processing device according to the first aspect of the present disclosure, the processor may include an element between the component in the preceding stage and the component in the succeeding stage, and may be configured to perform integral calculation by the element.

In the information processing device according to the first aspect of the present disclosure, the processor may be configured to implement the components that is output as the result of the determination in a circuit. The processor may be configured to perform a calculation process based on the circuit in which the components are implemented.

An information processing method of a second aspect of the present disclosure is executed by a computer. The method includes acquiring a calculation model, dividing the acquired calculation model at elements constituting the calculation model to generate a plurality of components, estimating a first index and a second index, making determination as to whether a third index is smaller than a preset threshold, and performing control to output a result of the determination. The first index is related to a calculation resource at a time when the calculation model is divided into the components. The second index is related to a calculation resource at a time when the calculation model is not divided into the components. The third index is calculated based on the first index and the second index.

Anon-transitory storage medium of a third aspect of the present disclosure stores instructions that are executable by one or more processors and that cause the one or more processors to perform functions. The functions include acquiring a calculation model, dividing the acquired calculation model at elements constituting the calculation model to generate a plurality of components, estimating a first index and a second index, making determination as to whether a third index is smaller than a preset threshold, and performing control to output a result of the determination. The first index is related to a calculation resource at a time when the calculation model is divided into the components. The second index is related to a calculation resource at a time when the calculation model is not divided into the components. The third index is calculated based on the first index and the second index.

With the information processing device of the first aspect of the present disclosure, an efficient calculation process can be performed. The information processing method of the second aspect and the non-transitory storage medium of the third aspect of the present disclosure can attain the same effect as that of the information processing device of the first aspect.

### BRIEF DESCRIPTION OF THE DRAWINGS

Features, advantages, and technical and industrial significance of exemplary embodiments of the present disclosure will be described below with reference to the accompanying drawings, in which like signs denote like elements, and wherein:

FIG. 1 is a diagram for describing an information processing system according to an embodiment;

FIG. 2 is a block diagram for describing an information processing device according to the embodiment;

FIG. 3 is a diagram for describing an example of a calculation model to be acquired by an acquisition unit;

FIG. 4 is a diagram for describing an example of a result of division by a division unit;

FIG. 5 is a diagram for describing an example of variables of a plurality of components divided by the division unit;

FIG. 6 is a first diagram for describing an example of implementation in a circuit by an implementation unit;

FIG. 7 is a second diagram for describing the example of the implementation in the circuit by the implementation unit;

FIG. 8 is a diagram for describing an example of a result of calculation performed by a calculation unit;

FIG. 9 is a diagram for describing a processing flow in an example;

FIG. 10 is a diagram for describing examples of integral calculation (integral communication); and

FIG. 11 is a flowchart for describing an information processing method according to the embodiment.

### DETAILED DESCRIPTION OF EMBODIMENTS

A term “information” is used herein. The term “information” can be rephrased as “data”, and the term “data” can be rephrased as “information”.

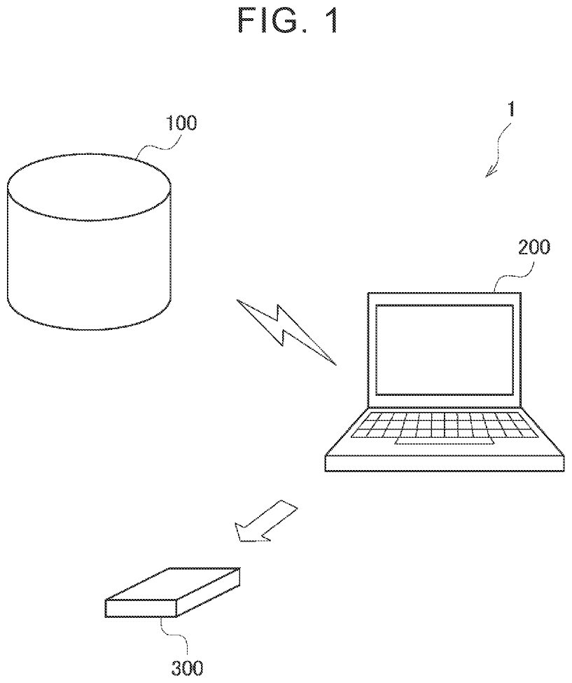

First, an outline of an information processing device 200 according to an embodiment will be described. FIG. 1 is a diagram for describing an information processing system 1 according to the embodiment.

The information processing system 1 includes the information processing device 200. For example, the information processing device 200 can communicate with a server 100. For example, the server 100 stores information on a calculation model to be simulated by the information processing device 200. For example, the information processing device 200 acquires the information on the calculation model from the server 100. Alternatively, the information processing device 200 may generate a calculation model and store the calculation model in a storage unit 222 (described later) or the like. The information processing device 200 acquires the calculation model generated by the information processing device 200 and the calculation model stored in the storage unit 222.

The information processing device 200 divides the calculation model into a plurality of components. For example, when the information processing device 200 divides the calculation model into the components, the information processing device 200 divides the calculation model so that the efficiency of calculation in each component increases. In this case, the information processing device 200 connects the divided components (for example, a component in a preceding stage and a component in a succeeding stage) so that integral communication can be performed between the divided components. In general, integral calculation provides an initial value, integration is performed by using the initial value and a current value, and a result of the integration is used in the next step. The integral communication enables communication of the integrated value for use in the next step by inserting the integral calculation in the middle of the communication process. The integral communication suppresses a decrease in calculation accuracy. The integral communication is communication utilizing the integral calculation while reducing the occurrence of delay. For example, in the integral communication, an integrator is interposed between a component in a preceding stage and a component in a succeeding stage. The integrator acquires a calculation result of the component in the preceding stage and performs the integral calculation. The integral communication may be communication in which the calculation result is output to both the component in the preceding stage and the component in the succeeding stage. Through the integral communication, the information processing device 200 enables parallel processing among the components.

For example, the information processing device 200 can implement the components capable of integral communication and generated as described above in a circuit 300 (convert the components to a logic circuit in the circuit and perform known pipeline processing). A field programmable gate array (FPGA) is an example of the circuit 300. For example, the information processing device 200 can perform a plurality of calculations (parallel processing) in one clock by implementing the calculation model in the FPGA. That is, the information processing device 200 simulates the calculation model by performing parallel calculations on the components using the circuit 300 (for example, the FPGA).

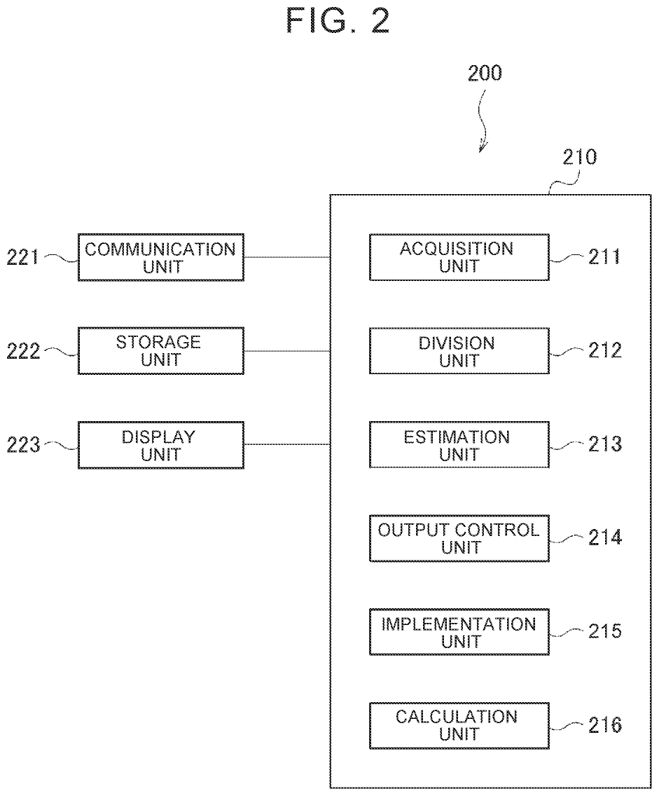

Next, details of the information processing device 200 will be described. FIG. 2 is a block diagram for describing functions of the information processing device 200 according to the embodiment.

The information processing device 200 includes a communication unit 221, the storage unit 222, a display unit 223, and a control unit 210. The communication unit 221, the storage unit 222, and the display unit 223 may be an example of “output unit”. For example, the control unit 210 may be implemented as a function of an arithmetic processing unit of the information processing device 200. The control unit 210 may function as an acquisition unit 211, a division unit 212, an estimation unit 213, an output control unit 214, an implementation unit 215, and a calculation unit 216.

For example, the communication unit 221 can communicate between the information processing device 200 and a device (external device) outside the information processing device 200 (for example, the server 100, a desktop, a laptop, a tablet, and a smartphone). For example, the communication unit 221 may receive information on a calculation model from the server 100 based on control of the control unit 210.

For example, the storage unit 222 stores various types of information and programs. For example, the storage unit 222 may store information on a calculation model generated in the information processing device 200 based on control of the control unit 210. Alternatively, the storage unit 222 may store, for example, information on a calculation model acquired from the server 100 via the communication unit 221 based on control of the control unit 210.

For example, the display unit 223 displays various characters, symbols, and images. For example, the display unit 223 may display the calculation model.

The acquisition unit 211 acquires the calculation model. For example, the acquisition unit 211 acquires the calculation model from the server 100 or the like via the communication unit 221. Alternatively, the acquisition unit 211 acquires, for example, the calculation model generated in the information processing device 200. Alternatively, the acquisition unit 211 acquires, for example, the calculation model stored in the storage unit 222. For example, the acquisition unit 211 may acquire a non-causal model using a physical equation-based physical component such as MATLAB Simscape. For example, the non-causal model need not clearly show a causal relationship between input and output. That is, the non-causal model may be, for example, a model in which the order of calculations is not fixed. For example, the information processing device 200 can perform non-causal modeling by describing behavior of a system and a component by a conservation law. The calculation model is generated as a physical network based on connection of physical components.

The division unit 212 divides the calculation model acquired by the acquisition unit 211 at elements constituting the calculation model to generate a plurality of components. For example, when the division unit 212 divides the calculation model into the components, the division unit 212 performs calculation on the components (for example, calculation by the integrator as an element capable of performing the integral calculation) based on an output value of the component in the preceding stage and an output value of the component in the succeeding stage. The calculation model may be divided to enable integral communication for outputting a calculation result to the component in the preceding stage and the component in the succeeding stage. In this case, the division unit 212 may arrange an element (for example, the integrator) between the component in the preceding stage and the component in the succeeding stage. The calculation (integral calculation) may be performed by the element (integrator). That is, the division unit 212 may divide the calculation model into the components to enable communication (integral communication) in which the calculation result of the component in the preceding stage (or the succeeding stage) is used in the component in the succeeding stage (or the preceding stage).

For example, the division unit 212 grasps elements of the calculation model, that is capable of the integral communication, and divides the calculation model at the positions of the elements to generate components. For example, the division unit 212 divides the calculation model into units capable of relatively cohesive calculations, and generates the units as components.

As described above, the integral communication enables the communication of the integrated value for use in the next step by, for example, inserting the integral calculation in the middle of the communication process. That is, the integral communication uses the integral calculation on the element (for example, the integrator) of the divided components to perform communication between the divided components. In the integral communication, signals are received from the divided components (model to be parallelized) and a summation/integration process is performed. In the integral communication, an output (output variable) of a result of the calculation process is sent (returned) to the components as a common signal. That is, the common signal is transmitted to the model to be parallelized. The integral communication can reduce the occurrence of communication delay variation due to the parallelization, by transmitting the common signal to the components in the preceding stage and the components in the succeeding stage at the same timing.

In other words, the integral communication may be, for example, a communication model in which the output from the component in the preceding stage and the output from the component in the succeeding stage are input to the element (integrator) to perform the integral calculation, and the result of the integral calculation is output to both the component in the preceding stage and the component in the succeeding stage.

A specific example of the integral communication is as follows. The control unit performs calculation (for example, integral calculation) by using the component in the preceding stage, and outputs a calculation result (first value) to the component in the succeeding stage. Similarly, the control unit performs calculation (for example, integral calculation) by using the component in the succeeding stage, and outputs a calculation result (second value) to the component in the preceding stage. The component in the preceding stage is synchronized with the component in the succeeding stage to repeat calculation (for example, integral calculation) by using the first value and the second value. Similarly, the component in the succeeding stage is synchronized with the component in the preceding stage to repeat calculation (for example, integral calculation) by using the first value and the second value. The integral communication is used for such calculation processes (integral calculation).

That is, the division unit 212 analyzes, for example, from the physical structure of the calculation model, parts (elements) serving as the integrators that can communicate by the integral process and perform parallel calculation to receive a common signal. Examples of the parts (mounted products corresponding to the elements) include a shaft connecting an engine and wheels of a vehicle, a capacitor arranged in an electronic circuit, and an “energy-storing component” that acquires and accumulates energy from each subsystem such as a gas state equation and feeds back common energy to each subsystem again. The division unit 212 generates a plurality of components (physical network) from the calculation model by performing division at the parts (elements). As a result, the information processing device 200 can reduce calculation variables and switch branches in the respective components, and can reduce the calculation amount of the entire calculation model. Initial values are set to the calculation model to be divided (components). The calculation model is discretized. That is, the integrator in numerical simulation has an initial value, and an output based on a calculation result by the integrator is used at the next time (step).

When a third index determined by a determination unit described later is equal to or larger than a threshold, the division unit 212 may generate a plurality of components by further division at an element constituting a component on which calculation is performed in the determination unit. That is, when the division unit 212 can further divide at least one generated component, the division unit 212 further grasps an element in the component, and divides the calculation model at the position of the element to generate a plurality of components. The component on which a third index determined by a determination unit described later is equal to or larger than a threshold may be an example of “the first component”.

The estimation unit 213 estimates a first index related to each calculation resource when the calculation model is divided into a plurality of components by the division unit 212, and a second index related to a calculation resource when the calculation model is not divided into a plurality of components by the division unit 212. For example, the first index indicates a necessary amount (for example, a variable) of calculation on each component. For example, when the calculation model is an electronic circuit, the variable may be a numerical value based on the number of switches serving as signal branching elements. For example, the second index indicates a necessary amount (for example, a variable) of calculation on the calculation model constituted by a plurality of components. Similarly to the case described above, when the calculation model is an electronic circuit, the variable in this case may be a numerical value based on the number of switches serving as signal branching elements.

The determination unit determines whether the third index calculated based on the first index and the second index that are estimated by the estimation unit 213 is smaller than a preset threshold. For example, the determination unit performs division with the first index as the numerator and the second index as the denominator. The determination unit may identify a component on which determination is made that the third index that is a numerical value obtained as a result of the division is smaller than the threshold.

That is, the determination unit calculates the third index by performing the division with the first index as the numerator and the second index as the denominator. For example, assuming that the first index is represented by A and the second index is represented by B, the third index represented by E is calculated by the following schematic expression (1).

E=A/B (1)

The calculation expression for calculating the third index E will be described in detail in an example described later.

When the value of the third index E is relatively small, determination is made, for example, that the calculation efficiency (the effect of reducing resources relative to labor of division into a plurality of components) is relatively high. When the value of the third index E is relatively large, determination is made, for example, that the calculation efficiency is relatively low. The determination unit sets a threshold and determines whether the calculation efficiency is high or low based on the threshold. That is, the determination unit determines that the calculation efficiency is high when the third index E is smaller than the threshold. The determination unit determines that the calculation efficiency is relatively low when the third index E is equal to or larger than the threshold. When the third index E is equal to or larger than the threshold, the division unit 212 further divides the calculation model (components) as described above to generate a plurality of new components. Even when the new components are generated, the estimation unit 213 and the determination unit perform the process described above.

The output control unit 214 controls the output unit to output a determination result obtained by the determination unit. That is, the output control unit 214 may control the output unit to output information on a component identified by the determination unit. As described above, the output unit may be the communication unit 221, the storage unit 222, and the display unit 223. The output control unit 214 controls the communication unit 221 to transmit information on the determination result (for example, the components) obtained by the determination unit to an external device. The output control unit 214 controls the storage unit 222 to store the information on the determination result (for example, the components) obtained by the determination unit. The output control unit 214 controls the display unit 223 to display the determination result (for example, the components) obtained by the determination unit.

The implementation unit 215 may perform implementation in the circuit 300 based on the components as the determination result output by the output control unit 214. That is, the implementation unit 215 performs implementation in the circuit 300 (for example, the FPGA) based on the components on which the determination unit determines that the third index E is smaller than the threshold. In this case, the implementation unit 215 converts physical equations corresponding to the components into state space equations. The implementation unit 215 discretizes the state space equations. That is, the implementation unit 215 performs conversion as a sequential expression from input to output. The implementation unit 215 combines the discretized state space equations (state space model) and the integral communication (discretized parallel communication model), and performs a process for implementation in the circuit 300 (for example, the FPGA). For example, the implementation unit 215 sets a data type of a numerical value to be calculated as the process for implementation in the circuit 300. In this case, the implementation unit 215 may set, for example, a fixed-point type or a single/double floating-point type. The implementation unit 215 may insert a delay register into the sequential calculation expression in order to synchronize a calculation cycle with clock timings of the circuit 300 (for example, the FPGA).

The calculation unit 216 may perform a calculation process based on the circuit 300 subjected to the implementation by the implementation unit 215. That is, the calculation unit 216 performs a simulation (calculation process) of the model implemented in the circuit 300 (for example, the FPGA). As a result, the calculation unit 216 can perform a simulation by parallel processing of the implemented model.

The output control unit 214 described above may control the output unit to output a calculation result obtained by the calculation unit 216 and the components (calculation results or the like) implemented in the circuit 300. The output control unit 214 controls the communication unit 221 to transmit information on, for example, the calculation result obtained by the calculation unit 216 to an external device. The output control unit 214 controls the storage unit 222 to store the information on, for example, the calculation result obtained by the calculation unit 216. The output control unit 214 controls the display unit 223 to display, for example, the calculation result obtained by the calculation unit 216.

### EXAMPLE

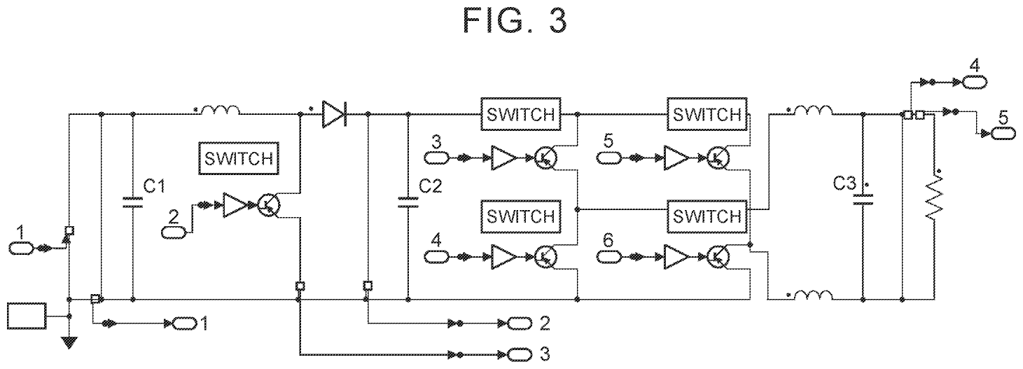

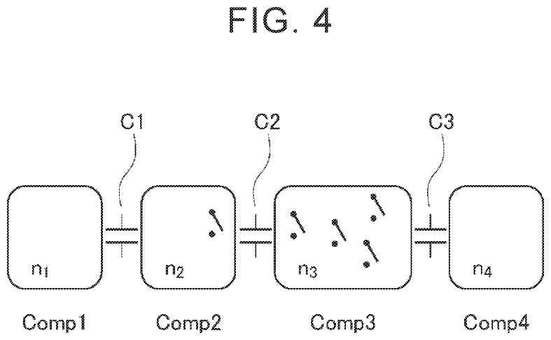

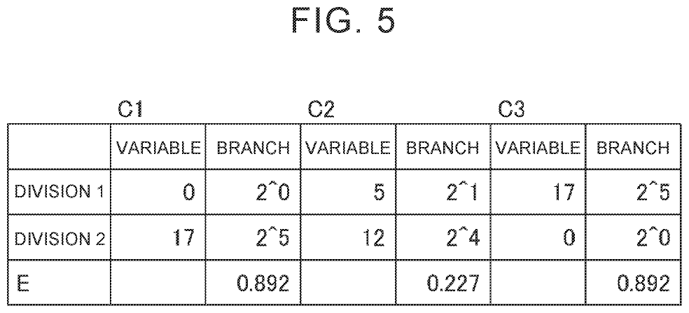

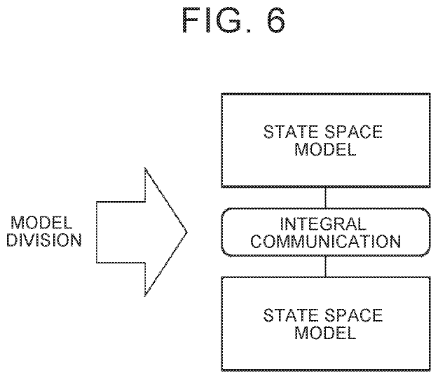

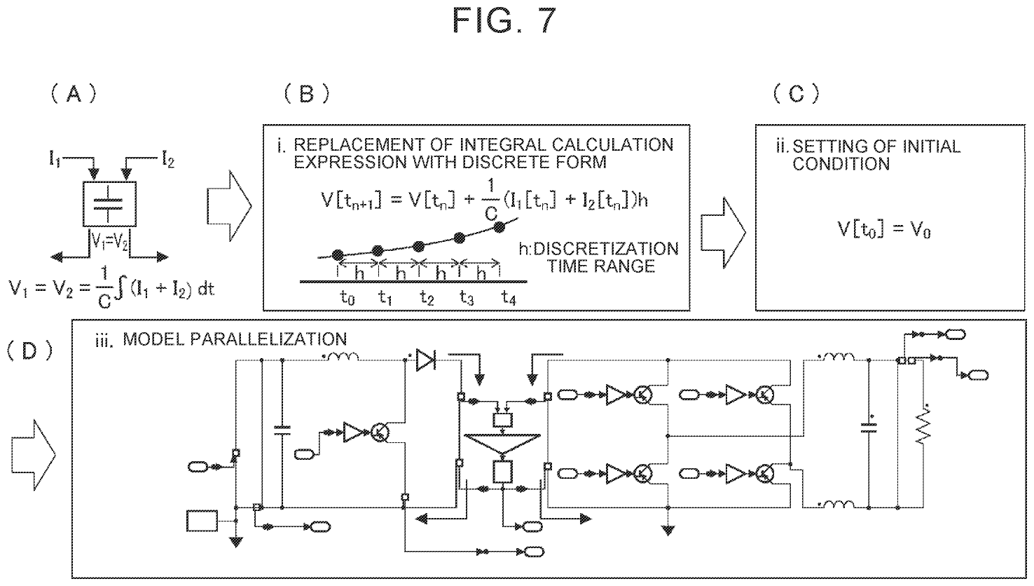

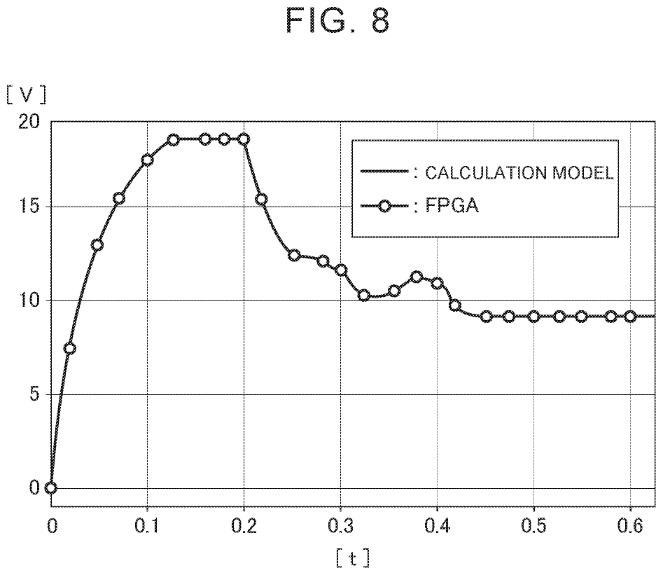

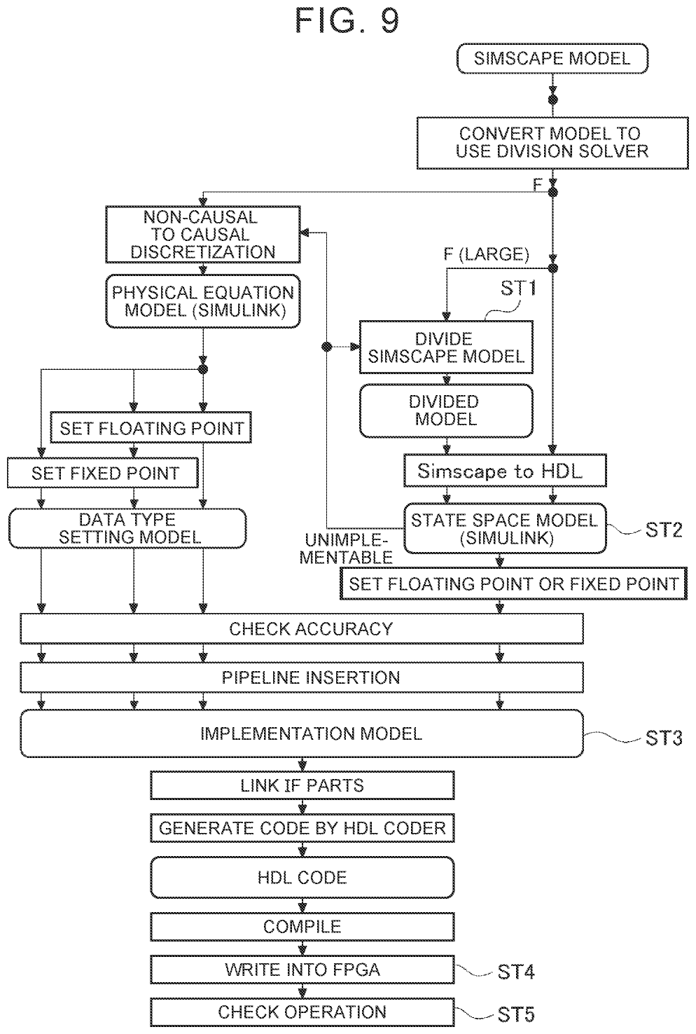

Next, an example of this embodiment will be described. FIG. 3 is a diagram for describing an example of a calculation model to be acquired by the acquisition unit 211. FIG. 4 is a diagram for describing an example of a result of division by the division unit 212. FIG. 5 is a diagram for describing an example of variables of a plurality of components divided by the division unit 212. FIG. 6 is a first diagram for describing an example of implementation in the circuit 300 by the implementation unit 215. FIG. 7 is a second diagram for describing the example of the implementation in the circuit 300 by the implementation unit 215. FIG. 8 is a diagram for describing an example of a result of calculation performed by the calculation unit 216. FIG. 9 is a diagram for describing a processing flow in the example.

First, the acquisition unit 211 acquires the calculation model in the example (schematic structure) of FIG. 3. For example, the calculation model in this case is an inverter electronic circuit including a plurality of capacitors. Three capacitors are connected to the electronic circuit exemplified in FIG. 3. The three capacitors are a first capacitor C1, a second capacitor C2, and a third capacitor C3.

Next, the division unit 212 performs division at elements constituting the calculation model to generate a plurality of components (Comps 1 to 4) as exemplified in FIG. 4. For example, the elements may be capacitors (C1 to C3). As illustrated in FIG. 4, the first component Comp1 has zero switches as branching elements, the second component Comp2 has one switch, the third component Comp3 has four switches, and the fourth component Comp4 has zero switches. In FIG. 4, the calculation model exemplified in FIG. 3 is divided at the elements, and the divided models after the division are set as the components (FIG. 4 illustrates an outline of the components).

When the calculation model is divided into the components by the division unit 212 as described above, for example, combinations of branches and variables taken by the calculation model depending on fluctuations of the branching elements (for example, the switches) of two components (Divisions 1 and 2) divided at any of the capacitors C1 to C3 are illustrated in FIG. 5.

Next, the estimation unit 213 estimates a first index related to each calculation resource when the calculation model is divided into a plurality of components by the division unit 212, and a second index related to a calculation resource when the calculation model is not divided into a plurality of components by the division unit 212. For example, the estimation unit 213 estimates the first index A by using the following expression (2).

A=X₁²2ⁿ^{₁}+X₂²2ⁿ^{₂} (2)

In this expression (2), “ni” (“n1” and “n2”) represents the number of branching elements (for example, the switches) included in the components generated by the division, and Xᵢ represents the number of variables in the divided network. The estimation unit 213 estimates the first index A of each of two components obtained by dividing the calculation model at the first capacitor C1 by the division unit 212, two components obtained by dividing the calculation model at the second capacitor C2 by the division unit 212, and two components obtained by dividing the calculation model at the third capacitor C3 by the division unit 212.

For example, the estimation unit 213 estimates the second index B by using the following expression (3).

B=Xₜₒₜ²2^{N} (3)

In this expression (3), Xₜₒₜ represents the number of variables in the entire model, and N represents the number of branching elements (for example, the switches) included in the entire model.

Next, the determination unit calculates the third index E based on the first index A and the second index B by using the following expression (4).

E=A/B (4)

That is, the third index E is represented by the following expression (5) by substituting the expressions (2) and (3) into the expression (4).

$$E = \frac{{X}_{1}^{2} {2}^{{n}_{1}} + {X}_{2}^{2} {2}^{{n}_{2}}}{{X}_{tot}^{2} {2}^{N}} \qquad ( 5 )$$

The determination unit determines whether the calculated third index E is smaller than the threshold. For example, the threshold may be 0.8. The threshold is not limited to 0.8, and may be any other numerical value. For example, when the third index E≥0.8, the determination unit may determine that the resource reduction effect relative to labor of division is small. For example, the determination unit performs division at a point of a minimum third index E when there is a plurality of points where the third index E<0.8. When further division is possible, the determination unit repeats the calculation using the expressions (2) to (4) based on the divided model, and divides the model into an optimum number of models.

Regarding the two components (Divisions 1 and 2) divided at the first capacitor C1, the two components (Divisions 1 and 2) divided at the second capacitor C2, and the two components (Divisions 1 and 2) divided at the third capacitor C3, the variables and branches calculated by the determination unit are illustrated in FIG. 5. As illustrated in FIG. 5, the third index E (branch) when the calculation model illustrated in FIG. 3 is divided at the first capacitor C1 is 0.892, the third index E (branch) when the calculation model is divided at the second capacitor C2 is 0.227, and the third index E (branch) when the calculation model is divided at the third capacitor C3 is 0.892. As a result, the determination unit determines that the third index E when the calculation model is divided at the second capacitor C2 is smaller than the threshold (0.8).

The implementation unit 215 implements the two components in the circuit 300 (for example, the FPGA) based on the determination result obtained by the determination unit, that is, the result showing that the calculation model is divided into the two components at the second capacitor C2. In this case, as exemplified in FIG. 6, the implementation unit 215 converts physical equations of the two components (model division) into state space equations (state space models), and connects the two state space models so that integral communication can be performed by the element (for example, the integrator). The state space equation is as follows.

x(t)=A(t)x(t)+B(t)u(t) (6)

y(t)=C(t)x(t)+D(t)u(t) (7)

In the expressions (6) and (7), “u” represents an input, “x” represents a state, and “y” represents an output.

That is, the implementation unit 215 sets the second capacitor C2 as an element (integrator) capable of performing integral calculation as illustrated in Part (A) of FIG. 7, and replaces an integral calculation expression with a discrete form as illustrated in Part (B) of FIG. 7. In this case, the implementation unit 215 sets an initial condition as illustrated in Part (C) of FIG. 7. As a result, the implementation unit 215 generates a model in which the two components are parallelized by the second capacitor C2 (integrator) as illustrated in Part (D) of FIG. 7. The implementation unit 215 implements such a model in the circuit 300 (for example, the FPGA).

Next, the calculation unit 216 performs a calculation process (simulation) of the model implemented in the circuit 300 by the implementation unit 215. The output control unit 214 controls the output unit to output a calculation result (simulation result) obtained by the calculation unit 216. In this example, in the model implemented in the circuit 300 (for example, the FPGA), for example, look-up tables (LUTs) are reduced by 36.6%, registers are reduced by 29.9%, and digital signal processors (DSPs) are reduced by 36.5% as compared with the calculation model. FIG. 8 is a graph showing time and voltage values in the circuit when the calculation process is performed by the calculation unit 216 and when the calculation is performed by using the calculation model. As exemplified in FIG. 8, comparison between a result of the calculation process performed by the calculation unit 216 (“FPGA” in FIG. 8) and a result of the calculation performed by using the calculation model (“calculation model” in FIG. 8) demonstrates that both of the results are substantially equal to each other (in the example of FIG. 8, “FPGA” and “calculation model” coincide with each other). It can be understood that the accuracy of the process performed in this embodiment is maintained.

The overall processing flow is illustrated in FIG. 9. Steps ST1 to ST5 will be described. In Step ST1, the division unit 212 performs a division process. In a series of processes in Steps ST2 to ST3, the implementation unit 215 creates state space models to create an implementation model. In Step ST4, the implementation unit 215 implements the model in the circuit 300 (for example, the FPGA). In Step ST5, the calculation unit 216 performs a calculation process (simulation process).

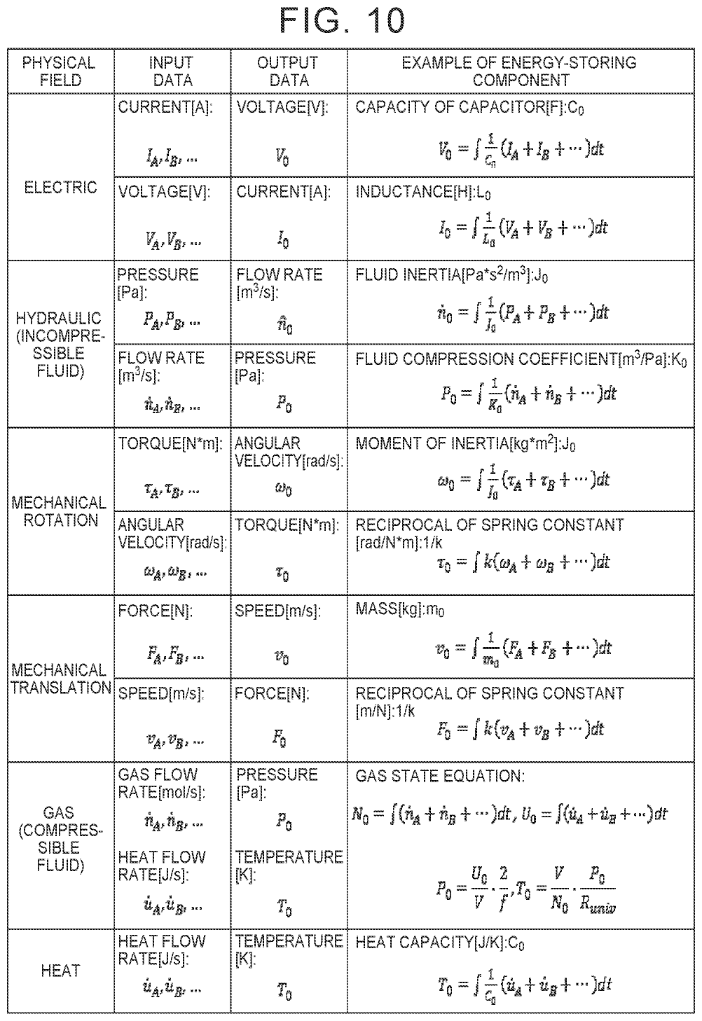

In the example described above, an example in which the calculation model of the electronic circuit is divided at the capacitor is described. However, the present disclosure is not limited to the example described above. FIG. 10 is a diagram for describing examples of the integral calculation (integral communication).

For example, the information processing device 200 may perform division at a coil of an electronic circuit, and perform the integral calculation (integral communication) based on inductance. For example, the information processing device 200 may perform division at any point in a hydraulic channel (incompressible fluid), and perform the integral calculation (integral communication) based on fluid inertia or a fluid compression coefficient. For example, the information processing device 200 may perform division at any point in a mechanical rotational model, and perform the integral calculation (integral communication) based on a moment of inertia or a reciprocal of a spring constant. For example, the information processing device 200 may perform division at any point in a mechanical translational model, and perform the integral calculation (integral communication) based on a mass or a reciprocal of a spring constant. For example, the information processing device 200 may perform division at any point in a gas channel (compressible gas), and perform the integral calculation (integral communication) based on a gas state equation. For example, the information processing device 200 may perform division at any point in a channel of a thermal fluid, and perform the integral calculation (integral communication) based on a heat capacity.

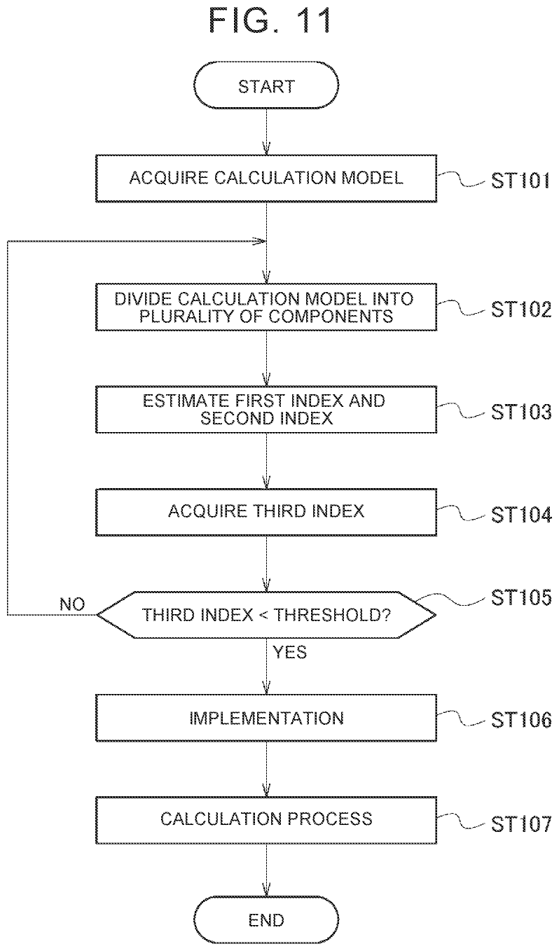

Next, an information processing method according to the embodiment will be described. FIG. 11 is a flowchart for describing the information processing method according to the embodiment.

In Step ST101, the acquisition unit 211 acquires a calculation model.

In Step ST102, the division unit 212 divides the calculation model acquired in Step ST101 at elements constituting the calculation model to generate a plurality of components. In this case, the division unit 212 may, for example, perform calculation on the components (for example, calculation by an integrator as an element capable of performing the integral calculation) based on an output value of the component in the preceding stage and an output value of the component in the succeeding stage, and perform division to enable integral communication for outputting a calculation result to the component in the preceding stage and the component in the succeeding stage. The division unit 212 may arrange an element (for example, the integrator) between the component in the preceding stage and the component in the succeeding stage, and perform the calculation (integral calculation) by the element (integrator).

In Step ST103, the estimation unit 213 estimates a first index and a second index. The first index is related to a calculation resource of each component when the calculation model is divided into the components in Step ST102. The second index is related to a calculation resource when the calculation model is not divided into the components in Step ST102 (calculation resource of the calculation model acquired in Step ST101).

In Step ST104, the determination unit acquires a third index by performing calculation based on the first index and the second index estimated in Step ST103. For example, the determination unit calculates the third index by using the expressions (2) to (4) described above.

In Step ST105, the determination unit determines whether the third index acquired in Step ST104 is smaller than the preset threshold. When the third index is smaller than the threshold (Yes in Step ST105), the process proceeds to Step ST106. When the third index is equal to or larger than the threshold (No in Step ST105), the process returns to Step ST102.

When the process returns to Step ST102 by determining “No” in Step ST105, the division unit 212 performs further division at an element constituting the component calculated in the determination unit to generate a plurality of components.

In Step ST106, the implementation unit 215 implements, in the circuit 300 (for example, an FPGA), the components on which determination is made in Step ST105 that the third index is smaller than the threshold.

In Step ST107, the calculation unit 216 performs a calculation process (simulation process) based on the circuit 300 in which the components are implemented in Step ST106.

Next, effects of this embodiment will be described. The information processing device 200 includes the division unit 212 configured to divide a calculation model at elements constituting the calculation model to generate a plurality of components, the estimation unit 213 configured to estimate the first index related to each calculation resource when the calculation model is divided into the components, and the second index related to a calculation resource when the calculation model is not divided into the components, the determination unit configured to determine whether the third index calculated based on the first index and the second index is smaller than the preset threshold, and the output control unit 214 configured to perform control to output a result of the determination. The information processing device 200 can perform an efficient calculation process. That is, the information processing device 200 can optimize the resources when the calculation model is implemented in the circuit 300 (for example, the FPGA). Therefore, the information processing device 200 can increase the speed when simulating the calculation model.

In the information processing device 200, the determination unit may perform division with the first index as the numerator and the second index as the denominator, and identify a component on which determination is made that the third index that is a numerical value obtained as a result of the division is smaller than the threshold. In this case, the output control unit 214 may perform control to output information on the component identified by the determination unit. As a result, the information processing device 200 can acquire a component capable of performing an efficient calculation process. That is, the information processing device 200 can divide the calculation model into a plurality of components that can relatively reduce the calculation amount when simulating the calculation model.

In the information processing device 200, when the third index determined by the determination unit is equal to or larger than the threshold, the division unit 212 may generate a plurality of components by further division at an element constituting the component on which calculation is performed in the determination unit. As a result, when the generated component can further be divided, the information processing device 200 performs division at the element in the component. Thus, an efficient calculation process can be performed.

In the information processing device 200, the division unit 212 may divide the components to enable the integral communication in which a calculation result of the component in the preceding stage is used in the component in the succeeding stage. As a result, in the information processing device 200, the calculation result of the component can be used by another component. That is, the information processing device 200 can perform parallel calculation in the simulation of the calculation model by performing the integral communication between the components. Therefore, the information processing device 200 can suppress a decrease in the calculation accuracy.

In the information processing device 200, the division unit 212 may arrange the element (for example, the integrator as the element capable of performing the integral calculation) between the component in the preceding stage and the component in the succeeding stage, and perform the integral calculation by the element. As a result, the information processing device 200 can reduce the occurrence of communication delay variation due to the parallelization when performing the parallel calculation using the components.

The information processing device 200 may include the implementation unit 215 configured to implement, in the circuit 300, the components as a determination result output by the output control unit 214, and the calculation unit 216 configured to perform the calculation process based on the circuit 300 in which the components are implemented by the implementation unit 215. As a result, the information processing device 200 can efficiently implement the non-causal calculation model constituted by the components in the circuit 300 (for example, the FPGA). The information processing device 200 can perform the parallel calculation process by the implementation in, for example, the FPGA as the circuit 300. Therefore, the information processing device 200 can perform a high-speed simulation. That is, the information processing device 200 can perform the calculation process (for example, FPGA simulation) without a decrease in the accuracy of the calculation model.

When the scale of the calculation model is large in the conversion of the non-causal calculation model, the calculation model cannot be implemented in the FPGA. That is, when the scale of the calculation model increases, the number of branching elements (for example, switches of an electronic circuit) increases, and the number of combinations of the branching elements becomes enormous. When the non-causal calculation model is converted into a state space equation and formulated as a causal equation, the number of modes taken by the state of the state space equation increases considerably. The resources at the time of implementation in the FPGA increase exponentially, and exceed resources that can be implemented in the FPGA. Even when the calculation model is divided, model-to-model communication for parallelization cannot be implemented in the FPGA. That is, the related-art model-to-model communication is described by an equation of a continuous system, and cannot be implemented in the FPGA unless a discretization process implementation procedure is added. The information processing device 200 of the present embodiment divides the calculation model at the position (element) where the calculation resource is small in the calculation model and the element capable of the integral communication. Thus, the resources can be optimized at the time of implementation in the circuit 300 (FPGA), and the speed can be increased when the calculation model is simulated. The information processing device 200 of the present embodiment can reduce the occurrence of communication delay variation by the integral communication, and suppress the decrease in the accuracy of the simulation.

In the information processing method, a computer executes a division step for dividing a calculation model at elements constituting the calculation model to generate a plurality of components, an estimation step for estimating the first index related to each calculation resource when the calculation model is divided into the components, and the second index related to a calculation resource when the calculation model is not divided into the components, a determination step for determining whether the third index calculated based on the first index and the second index and related to resources necessary for calculation is smaller than the preset threshold, and an output control step for performing control to output a result of the determination. In the information processing method, an efficient calculation process can be performed. That is, in the information processing method, the resources can be optimized when the calculation model is implemented in the circuit 300 (for example, the FPGA). Therefore, the information processing method can increase the speed when simulating the calculation model.

An information processing program causes a computer to implement a division function for dividing a calculation model at elements constituting the calculation model to generate a plurality of components, an estimation function for estimating the first index related to each calculation resource when the calculation model is divided into the components, and the second index related to a calculation resource when the calculation model is not divided into the components, a determination function for determining whether the third index calculated based on the first index and the second index and related to resources necessary for calculation is smaller than the preset threshold, and an output control function for performing control to output a result of the determination. In the information processing program, an efficient calculation process can be performed. That is, in the information processing program, the resources can be optimized when the calculation model is implemented in the circuit 300 (for example, the FPGA). Therefore, the information processing program can increase the speed when simulating the calculation model.

Each part of the information processing device 200 may be implemented as, for example, functions of an arithmetic processing unit (processor) of a computer. That is, the acquisition unit 211, the division unit 212, the estimation unit 213, the output control unit 214, and the calculation unit 216 (control unit 210) of the information processing device 200 may be implemented as an acquisition function, a division function, an estimation function, an output control function, and a calculation function (control function) by the arithmetic processing unit of the computer. The information processing program can cause the computer to implement the functions described above. The information processing program may be recorded on a non-transitory computer-readable recording medium such as an external memory or an optical disc. As described above, each part of the information processing device 200 may be implemented by, for example, the arithmetic processing unit of the computer. For example, the arithmetic processing unit includes an integrated circuit. Therefore, each part of the information processing device 200 may be implemented as the circuit constituting the arithmetic processing unit. That is, the acquisition unit 211, the division unit 212, the estimation unit 213, the output control unit 214, and the calculation unit 216 (control unit 210) of the information processing device 200 may be implemented as an acquisition circuit, a division circuit, an estimation circuit, an output control circuit, and a calculation circuit (control circuit) constituting the arithmetic processing unit of the computer. The communication unit 221, the storage unit 222, and the display unit 223 (output unit) and the implementation unit 215 of the information processing device 200 may be implemented as, for example, a communication function, a storage function, and a display function (output function) and an implementation function in the functions of the arithmetic processing unit. The communication unit 221, the storage unit 222, and the display unit 223 (output unit) and the implementation unit 215 of the information processing device 200 may be implemented as, for example, a communication circuit, a storage circuit, and a display circuit (output circuit) and an implementation circuit by using an integrated circuit. The communication unit 221, the storage unit 222, and the display unit 223 (output unit) and the implementation unit 215 of the information processing device 200 may be implemented as, for example, a communication device, a storage device, and a display device (output device) and an implementation device by using a plurality of devices.

What is claimed is:

1. An information processing device comprising a processor configured to:
acquire a calculation model;
divide the acquired calculation model at elements constituting the calculation model to generate a plurality of components;
estimate a first index and a second index, the first index being related to a calculation resource at a time when the calculation model is divided into the components, the second index being related to a calculation resource at a time when the calculation model is not divided into the components;
make determination whether a third index is smaller than a preset threshold, the third index being calculated based on the first index and the second index; and
perform control to output a result of the determination.

2. The information processing device according to claim 1, wherein the processor is configured to:
identify a component that the processor makes the determination that the third index is smaller than the threshold, the third index being calculated by division with the first index as a numerator and the second index as a denominator; and
output information on the identified component.

3. The information processing device according to claim 1, wherein the processor is configured to, when the processor determines that the third index is equal to or larger than the threshold, further divide a first component at an element constituting the first component to further generate a plurality of components, the first component being a component on which the determination is made that the third index is equal to or larger than the threshold.

4. The information processing device according to claim 1, wherein the processor is configured to divide the calculation model such that the components to perform integral communication for using a calculation result of a component in a preceding stage in a component in a succeeding stage.

5. The information processing device according to claim 4, wherein the processor includes an element between the component in the preceding stage and the component in the succeeding stage, and is configured to perform integral calculation by the element.

6. The information processing device according to claim 1, wherein the processor is configured to:
implement the components that is output as the result of the determination in a circuit; and
perform a calculation process based on the circuit in which the components are implemented.

7. An information processing method to be executed by a computer, the information processing method comprising:
acquiring a calculation model;
dividing the acquired calculation model at elements constituting the calculation model to generate a plurality of components;
estimating a first index and a second index, the first index being related to a calculation resource at a time when the calculation model is divided into the components, the second index being related to a calculation resource at a time when the calculation model is not divided into the components;
making determination whether a third index is smaller than a preset threshold, the third index being calculated based on the first index and the second index; and
performing control to output a result of the determination.

8. A non-transitory storage medium storing instructions that are executable by one or more processors and that cause the one or more processors to perform functions comprising:
acquiring a calculation model;
dividing the acquired calculation model at elements constituting the calculation model to generate a plurality of components;
estimating a first index and a second index, the first index being related to a calculation resource at a time when the calculation model is divided into the components, the second index being related to a calculation resource at a time when the calculation model is not divided into the components;
making determination as to whether a third index is smaller than a preset threshold, the third index being calculated based on the first index and the second index; and
performing control to output a result of the determination.
